(19) United States
(12) Patent Application Publication
(10) Pub. No.: US 2025/0294921 A1
(43) Pub. Date: Sep. 18, 2025

(54) METHOD FOR MANUFACTURING SEMICONDUCTOR LIGHT-EMITTING DEVICE HAVING COLOR CONVERSION TECHNOLOGY APPLIED THERETO

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,652

(22) PCT Filed: Sep. 18, 2023
(86) PCT No.: PCT/KR2023/014071

§ 371 Date: Oct. 27, 2024

(30) Foreign Application Priority Data
Sep. 19, 2022 (KR) 10-2022-0117788
Dec. 26, 2022 (KR) 10-2022-0184183

(51) Int. Cl. H10H 20/01

(52) U.S. Cl. CPC H10H 20/017; H10H 20/0361; H10H 20/0362; H10H 20/0364

(57) ABSTRACT

The present invention relates to a method for manufacturing a semiconductor light-emitting device having color conversion technology applied thereto, wherein color conversion technology has been applied to one epitaxial die in which only one of two electrodes is exposed to the outside and which emits blue or ultraviolet rays, enabling the manufacture of a semiconductor light-emitting device emitting each of blue, green, and red light.

### TECHNICAL FIELD

The present invention relates to a method of manufacturing a semiconductor light-emitting device employing a color conversion technique.

### BACKGROUND ART

In general, micro light-emitting diode (LED) displays (including mini LED displays) can be classified into micro LED displays with a passive matrix (PM) driving method and micro LED displays with an active matrix (AM) driving method.

Here, PM-driven micro LED displays typically have a sapphire support substrate, which finally remains, and use sorted thick blue, green, and red (BGR) chips (with both fully fabricated positive and negative electrodes of the LED), which are transferred using a chip die-level process in which either horizontal chips or flip chips can be generally utilized.

In addition, AM-driven micro LED displays typically do not have a sapphire support substrate, which finally remains, and use unsorted thin blue, green, and red (BGR) chips (with both fully fabricated positive and negative electrodes of the LED), which are transferred using a wafer-level process in which horizontal chips, flip chips, or vertical chips can all be generally utilized.

These conventional typical PM- and AM-driven micro LED displays have the following common issues.

First, when considering the application of vertical chips to reduce chip die size, there is a problem that, unlike flip chips, which allow defects to be immediately confirmed after bonding, in the case of vertical chips, defects can only be confirmed after bonding and subsequent upper wiring.

Further, in terms of a bonding process, higher precision is required in the bonding process due to the reduction in chip die size, and improved bonding strength is required due to the reduction in bonding area.

Further, in terms of a tiling process in which a plurality of unit displays are combined like tiles, there is an issue in which boundaries between the unit displays become distinct when the displays are turned off or show a black screen, and this is more noticeable in the PM driving method compared to the AM driving method. In addition, although many aspects have been improved, there is still an issue in which boundaries are visible on monochromatic screens and still images, and when using thin-film transistor (TFT) glass panels for tiling, the process is challenging due to the risk of glass breakage. Further, due to the tolerance relationship between pixel pitch and tiling boundaries, various issues exist, including the expectation that the tiling process will be difficult to apply to products smaller than 100 inches.

Meanwhile, in the conventional PM-driven micro LED displays, the reduction in chip die size is the greatest challenge. That is, from an aspect ratio perspective, achieving a reduction in chip die size essentially requires decreasing a thickness of a sapphire final support substrate, but the current limit for the thickness of the sapphire support substrate is about 80 μm to 70 μum, and when the thickness is reduced below 50 μm, a substrate breaking issue occurs. Further, there are complex issues related to chip measurement and classification in this type of micro LED display, and it is expected that flip chips will be mainly used in this type of display rather than horizontal and vertical chips, but when the flip chips are used, high-precision and high-speed bonding processes, as well as materials for them, are separately required.

Further, in conventional AM-driven micro LED displays, in which the final support substrate is not present and chip die size reduction is possible, there are issues related to resolving defects (No Good, NG). That is, the fundamental issues in epitaxial and fab processes, such as yield improvement related to wavelength and electrical characteristics at the chip-on-wafer (COW) level, have not been resolved, and there is difficulty in 100% sorting and removal of defective (NG) chips. In order to address these issues, approaches such as redundancy have been recently attempted, but have not provided a fundamental solution.

### DISCLOSURE

### Technical Problem

The present invention is directed to solving the above-described conventional problems and providing a method of manufacturing a semiconductor light-emitting device employing a color conversion technique, enabling a semiconductor light-emitting device that emits blue, green, or red light to be manufactured by applying the color conversion technique to one epitaxial die, in which only one of two electrodes is exposed to the outside and which emits blue or ultraviolet light.

### Technical Solution

The above objective is achieved by a method of manufacturing a semiconductor light-emitting device employing a color conversion technique, including a first operation of preparing an epitaxial die including a support substrate, a light-emitting part that generates light, an ohmic electrode electrically connected to the light-emitting part through an ohmic contact, a contact electrode that is not exposed to the outside, and a bonding pad layer that is exposed to the outside, and preparing a substrate part on which a first electrode pad and a second electrode pad are formed, a second operation of placing the epitaxial die on the first electrode pad, and bonding and electrically connecting the first electrode pad and the bonding pad layer through a bonding layer, a third operation of separating the support substrate, a fourth operation of dividing the epitaxial die into a plurality of regions by etching the epitaxial die, and exposing the contact electrode in each of the divided regions, and a fifth operation of forming an extension electrode that electrically connects the second electrode pad and the exposed contact electrode.

### Advantageous Effects

According to the present invention, a semiconductor light-emitting device that emits blue, green, or red light can be manufactured using one epitaxial die, which facilitates defect sorting, allows the use of existing general-purpose transfer equipment as it is to reduce process and facility investment costs, and enables a dramatic reduction in thickness and chip die size while improving light output by removing a sapphire final support substrate, thereby significantly reducing a size and thickness of a semiconductor light-emitting device.

Further, according to the present invention, unlike conventional chip dies in which two electrodes, i.e., a positive electrode and a negative electrode, are exposed to the outside, an epitaxial die of the present invention has a structure in which only one electrode is exposed to the outside, and thus, although the epitaxial die is not electrically sorted, the epitaxial die can be optically sorted, so that defects (NG) can be easily identified initially by a high-speed photoluminescence (PL) measurement method or the like using only optical characteristics (wavelength, full width half maximum (FWHM), intensity, and the like), and electrical defects of the epitaxial die can be easily detected and defective epitaxial dies can be easily repaired or replaced before an upper wiring process.

Further, according to the present invention, an epitaxial die of the present invention has the advantage that a process of forming a p-ohmic contact electrode or an n-ohmic contact electrode, which requires a high-temperature heat treatment of 300° C. or higher, is completed in the operation of manufacturing the epitaxial die, so that the epitaxial die of the present invention does not require a high-temperature heat treatment process after transfer.

Further, according to the present invention, an epitaxial die of the present invention has the advantage of having a sapphire final support substrate attached, which can be removed after being transferred onto a targeted wafer, thereby enabling the die to be repositioned through conventional chip die transfer processes such as pick-and-place and replace.

Meanwhile, the effects of the present invention are not limited to the above-mentioned effects, and various effects may be included within the scope which is apparent to those skilled in the art from content to be described below.

### DESCRIPTION OF DRAWINGS

FIG. 1 is a flowchart of a method of manufacturing a semiconductor light-emitting device employing a color conversion technique according to a first embodiment of the present invention.

FIGS. 2 to 5 illustrate a process of manufacturing the semiconductor light-emitting device employing a color conversion technique according to the first embodiment of the present invention.

FIG. 6 illustrates that an epitaxial die of the semiconductor light-emitting device employing a color conversion technique according to the first embodiment of the present invention includes an etching stop layer.

FIG. 7 illustrates a fourth operation of the method of manufacturing the semiconductor light-emitting device employing a color conversion technique according to the first embodiment of the present invention, in which the epitaxial die is etched and divided into a plurality of regions.

FIG. 8 is a flowchart of a method of manufacturing a semiconductor light-emitting device employing a color conversion technique according to a second embodiment of the present invention.

FIG. 9 illustrates a process of manufacturing the semiconductor light-emitting device employing a color conversion technique according to the second embodiment of the present invention.

FIG. 10 is a flowchart of a method of manufacturing a semiconductor light-emitting device employing a color conversion technique according to a third embodiment of the present invention.

FIG. 11 illustrates a process of manufacturing the semiconductor light-emitting device employing a color conversion technique according to the third embodiment of the present invention.

FIG. 12 is a flowchart of a method of manufacturing a semiconductor light-emitting device employing a color conversion technique according to a fourth embodiment of the present invention.

FIG. 13 illustrates a process of manufacturing the semiconductor light-emitting device employing a color conversion technique according to the fourth embodiment of the present invention.

FIG. 14 is a flowchart of a method of manufacturing a semiconductor light-emitting device employing a color conversion technique according to a fifth embodiment of the present invention.

FIG. 15 illustrates a process of manufacturing the semiconductor light-emitting device employing a color conversion technique according to the fifth embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even when shown in different drawings.

In addition, in describing the embodiments of the present invention, when detailed descriptions of related known structures or functions may obscure the gist of the present invention, the detailed description thereof will be omitted.

In addition, terms such as “first,” “second,” “A,” “B,” “(a),” “(b),” and the like may be used herein to describe components of the embodiments of the present invention. These terms are not used to define an essence, order, or sequence of a corresponding component but merely to distinguish the corresponding component from other component(s).

The present invention relates to a method of manufacturing a semiconductor light-emitting device, which emits blue, green, or red light, by applying a color conversion technique to one epitaxial die that emits blue or ultraviolet light. In the present invention, a semi-finished light source die with a size less than or equal to that of a mini light-emitting diode (LED), which can be sorted and has the following characteristics, is defined as the epitaxial die of the present invention.

First, unlike conventional chip dies in which two electrodes, i.e., a positive electrode and a negative electrode, are both exposed to the outside, the epitaxial die of the present invention has a structure in which only one electrode is exposed to the outside. Accordingly, in the epitaxial die of the present invention, since only one (contact electrode) of two electrodes is exposed to the outside, even though the epitaxial die is not electrically sorted, the epitaxial die can be optically sorted, so that defects (NG) can be easily identified initially by a high-speed photoluminescence (PL) measurement method or the like using only optical characteristics (wavelength, full width half maximum (FWHM), intensity, and the like), and electrical defects of the epitaxial die can be easily detected and defective epitaxial dies can be easily replaced before an upper wiring process.

Second, in the epitaxial die of the present invention, a process of forming a p-ohmic contact electrode or an n-ohmic contact electrode, which requires a high-temperature heat treatment of 300° C. or higher, is completed in the operation of manufacturing the epitaxial die. Accordingly, the epitaxial die of the present invention has the advantage of not requiring a high-temperature heat treatment process after transfer to a substrate.

Third, the epitaxial die of the present invention includes a final sapphire support substrate attached thereto, which is removed after transfer. Accordingly, the epitaxial die of the present invention has the advantage of being repositionable through conventional chip die transfer processes such as pick-and-place and replace.

That is, the epitaxial die of the present invention can simultaneously satisfy both the advantage of a mini light-emitting diode (LED) manufacturing process, such as ease of defect classification, and low process and facility investment costs due to the use of existing general-purpose transfer equipment as it is, and the advantage of a micro LED manufacturing process, such as a dramatic reduction in thickness and a reduction in chip die size by removing a final support substrate, which is the final substrate, thereby improving light output.

Further, the semiconductor light-emitting device of the present invention may be formed as a chip-on-board (COB) in which individual chips or epitaxial die units are directly transferred and connected to a substrate (such as a semiconductor wafer, a printed circuit board (PCB), or thin-film transistor (TFT) glass) on which circuit wiring and driving element regions are completed, a package-on-board (POB) in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using the intermediate temporary substrate on which circuit wiring and driving element regions are not completed, but is not limited thereto, and will be described herein as being formed as the COB type for convenience of description.

Meanwhile, in the present invention, the substrate onto which the epitaxial die is transferred may include through-silicon vias (TSVs), through-glass vias (TGVs), through-sapphire vias (TSaVs), through-AAO vias (TAVs), through-zirconia vias (TZVs), through-polyimide vias (TPoVs), through-resin vias (TRVs), and the like, in which via holes are formed first, and then electrode posts are formed in the corresponding via holes.

Hereinafter, with reference to the accompanying drawings, a method (S10) of manufacturing a semiconductor light-emitting device employing a color conversion technique according to a first embodiment of the present invention will be described in detail.

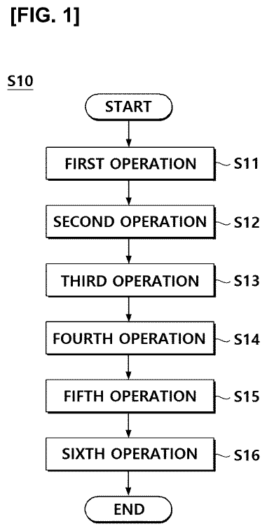

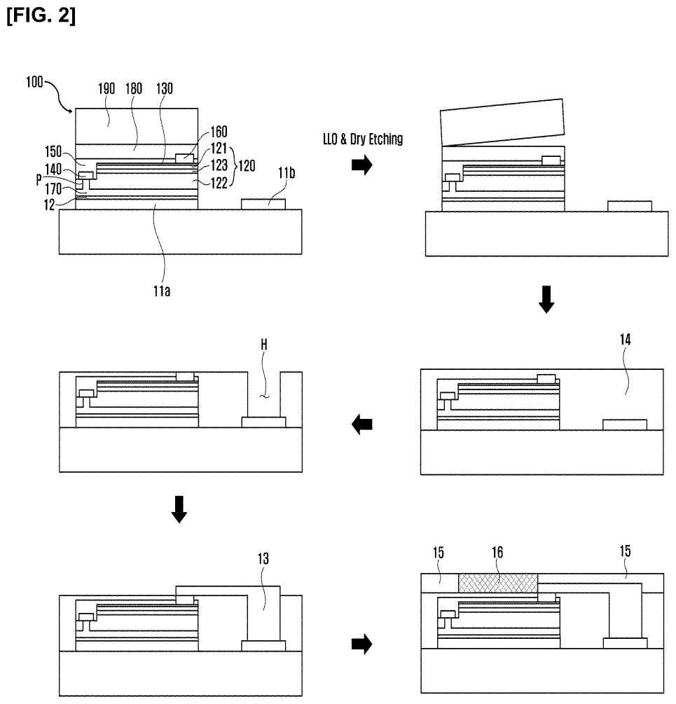

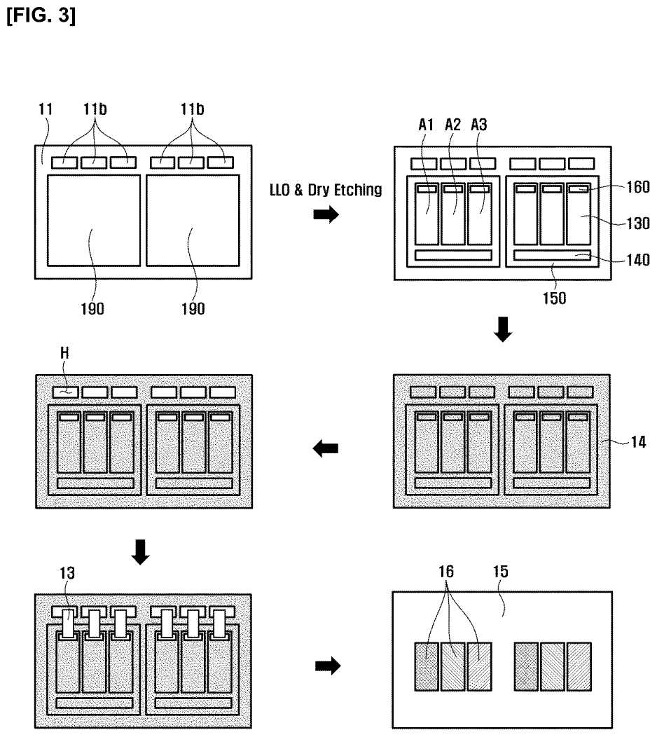

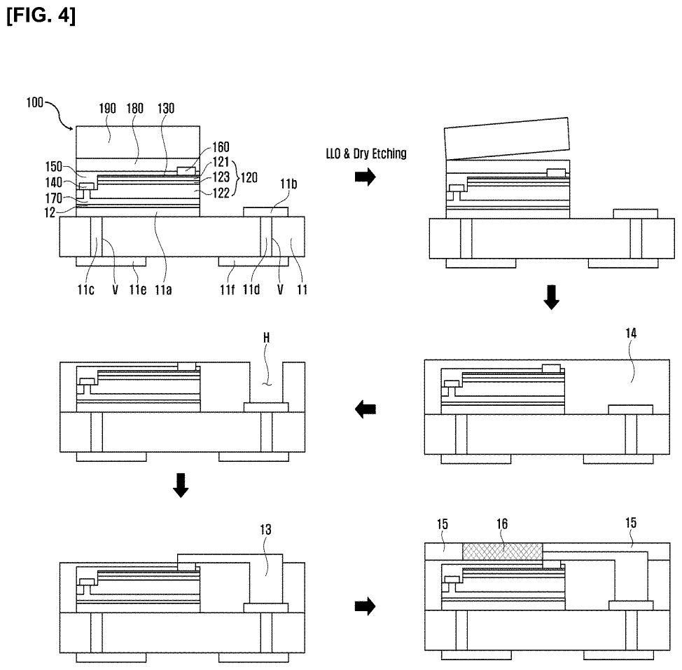

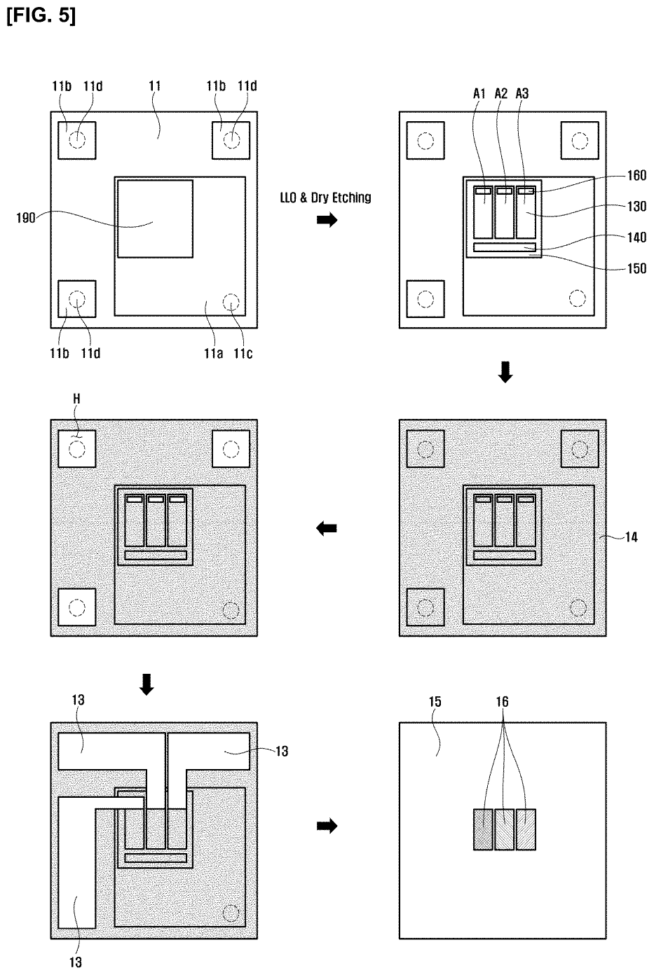

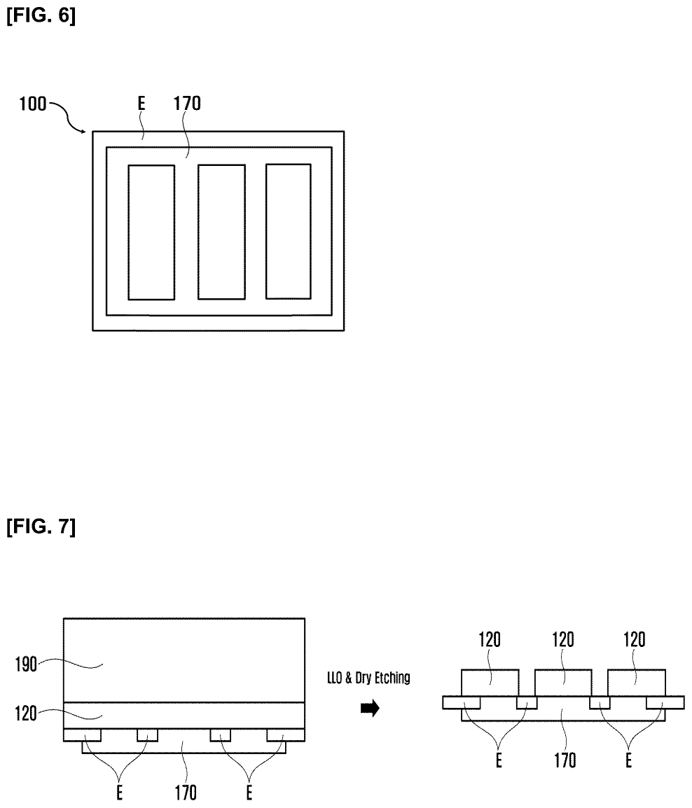

FIG. 1 is a flowchart of the method of manufacturing the semiconductor light-emitting device employing a color conversion technique according to the first embodiment of the present invention, FIGS. 2 to 5 illustrate a process of manufacturing the semiconductor light-emitting device employing a color conversion technique according to the first embodiment of the present invention, FIG. 6 illustrates that an epitaxial die of the semiconductor light-emitting device employing a color conversion technique according to the first embodiment of the present invention includes an etching stop layer, and FIG. 7 illustrates a fourth operation of the method of manufacturing the semiconductor light-emitting device employing a color conversion technique according to the first embodiment of the present invention, in which the epitaxial die is etched and divided into a plurality of regions.

As shown in FIGS. 1 and 7, the method (S10) of manufacturing the semiconductor light-emitting device employing a color conversion technique according to the first embodiment of the present invention includes a first operation S11, a second operation S12, a third operation S13, a fourth operation S14, a fifth operation S15, and a sixth operation S16. However, it is of course possible to change the order of the processes shown in FIGS. 1 and 7.

The first operation S11 is an operation of preparing an epitaxial die 100 according to the first embodiment of the present invention and a substrate part 11.

The substrate part 11 supports the epitaxial die 100 that is bonded thereto, and a first upper electrode pad 11a and a second upper electrode pad 11b may be formed on an upper surface of the substrate part 11.

In addition, the substrate part 11 has a first electrode post 11c and a second electrode post 11d formed through via holes V formed therein, and the first upper electrode pad 11a electrically connected to the first electrode post 11c at an upper portion of the first electrode post 11c, the second upper electrode pad 11b electrically connected to the second electrode post 11d at an upper portion of the second electrode post 11d, a first lower electrode pad 11e electrically connected to the first electrode post 11c at a lower portion of the first electrode post 11c, and a second lower electrode pad 11f electrically connected to the second electrode post 11d at a lower portion of the second electrode post 11d may be formed.

Such a substrate part 11 may be a semiconductor wafer, a PCB, TFT glass, an interposer, or the like. Furthermore, the substrate part 11 may be a structure including through-silicon vias (TSVs), through-glass vias (TGVs), through-sapphire vias (TSaVs), through-AAO vias (TAVs), through-zirconia vias (TZVs), through-polyimide vias (TPoVs), and through-resin vias (TRVs), in which a plurality of via holes V are formed first, and then electrode posts 11c and 11d are formed in the corresponding via holes V, but the present invention is not limited thereto.

Meanwhile, in the present invention, the first upper electrode pad 11a may be provided as a common electrode, and the second upper electrode pad 11b may be provided as a plurality of individual electrodes. When the first upper electrode pad 11a is a common negative electrode, the second upper electrode pad 11b may be an individual positive electrode, and when the first upper electrode pad 11a is a common positive electrode, the second upper electrode pad 11b may be an individual negative electrode, which may vary depending on the characteristics of the epitaxial die 100 (e.g., the polarity of a bonding pad layer 170).

In addition, the first electrode post 11c and the second electrode post 11d may each be formed in the shape of a column (a post) in the via hole V that passes through the substrate part 11, using copper (Cu) plating (or by inserting a nickel (Ni) wire), and in this case, the via hole V may be formed at each of four corner portions of the substrate part 11 to enhance a bonding strength of the substrate part 11 through a plurality of electrode posts 11c and 11d. For example, when the epitaxial die 100 that emits blue or ultraviolet light is transferred (placed) onto the substrate part 11, one first electrode post 11c, which is a common electrode, may be formed in the via hole V at the corner portion of the substrate part 11, and three second electrode posts 11d, which are individual electrodes, may be formed in the via holes V of the remaining corner portions of the substrate part 11. Subsequently, the first electrode post 11c may be electrically connected to the bonding pad layer 170 of the epitaxial die 100, and the second electrode post 11d may be electrically connected to the contact electrode 160 of the epitaxial die 100 through an extension electrode 13, which will be described below.

Further, the epitaxial die 100 according to the first embodiment of the present invention includes a light-emitting part 120 that generates light, a first ohmic electrode 130, a second ohmic electrode 140, a passivation layer 150, a contact electrode 160 that is not exposed to the outside, the bonding pad layer 170 that is exposed to the outside, a temporary bonding layer 180, and a final support substrate 190.

The light-emitting part 120 generates light, and in the present invention, in order to emit blue or ultraviolet light, binary, ternary, and quaternary compounds such as indium nitride (InN), indium gallium nitride (InGaN), gallium nitride (GaN), aluminum gallium nitride (AlGaN), aluminum nitride (AIN), and aluminum gallium indium nitride (AlGaInN), which are Group III (Al, Ga, and In) nitride semiconductors, may be epitaxially grown on an initial growth substrate by being placed in appropriate positions and sequences.

In particular, in order to emit blue light, high-quality indium gallium nitride (InGaN) with a high indium (In) composition, which is a Group III nitride semiconductor, should preferentially be formed on Group III nitride semiconductors composed of gallium nitride (GaN), aluminum gallium nitride (AlGaN), aluminum nitride (AlN), and aluminum gallium indium nitride (AlGaInN), but the present invention is not limited thereto. In addition, unlike in the case of blue light, to emit ultraviolet light, it is preferable to use high-quality indium gallium nitride (InGaN) with a lower indium (In) composition or a Group III nitride semiconductor containing a certain amount of aluminum (Al).

More specifically, the light-emitting part 120 includes a first semiconductor region 121 (e.g., a p-type semiconductor region), an active region 123 (e.g., multi-quantum wells (MQWs)), and a second semiconductor region 122 (e.g., an n-type semiconductor region), and the light-emitting part 120 may have a structure in which the second semiconductor region 122, the active region 123, and the first semiconductor region 121 are epitaxially grown in that order on the initial growth substrate, and ultimately, may have an overall thickness typically ranging from about 5.0 to 8.0 μm, including multiple layers of group III nitrides, but the present invention is not limited thereto.

Each of the first semiconductor region 121, the active region 123, and the second semiconductor region 122 may be formed as either a single layer or multiple layers, and although not shown in the drawing, necessary layers, such as buffer regions, may be added before the light-emitting part 120 is epitaxially grown on an initial sapphire growth substrate to ensure the high quality of the epitaxially grown light-emitting part 120. For example, the buffer regions may include a nucleation layer and a compliant layer composed of an un-doped semiconductor region to relieve stress and improve thin-film quality and typically have a thickness of about 4.0 μm. In addition, when the final support substrate 190 is removed using a laser lift-off (LLO) technique, a sacrificial layer may be provided between the nucleation layer and the un-doped semiconductor region, and a seed layer may function as the sacrificial layer.

The second semiconductor region 122 has a second conductivity type (n-type), and is formed on the initial growth substrate. The second semiconductor region 122 may have a thickness of 2.0 to 3.5 μm.

The active region 123 generates light using the recombination of electrons and holes and is formed on the second semiconductor region 122. The active region 123 may have a multi-layer structure primarily composed of indium gallium nitride (InGaN) and gallium nitride (GaN) semiconductors, and may have a thickness of several tens of nanometers (nm).

The first semiconductor region 121 has a first conductivity type (p-type), and is formed on the active region 123. The first semiconductor region 121 may have a multi-layer structure primarily composed of aluminum gallium nitride (AlGaN) and gallium nitride (GaN) semiconductors, may have a thickness ranging from several tens of nanometers (nm) to several micrometers (μm), and includes an upper surface having gallium (Ga) polarity.

That is, the active region 123 is interposed between the first semiconductor region 121 and the second semiconductor region 122, and light is generated when holes in the first semiconductor region 121, which is a p-type semiconductor region, and electrons in the second semiconductor region 122, which is an n-type semiconductor region, recombine in the active region 123.

Meanwhile, the light-emitting part 120, which is epitaxially grown on the initial growth substrate in the order of the second semiconductor region 122, the active region 123, and the first semiconductor region 121, has a structure in which the first semiconductor region 121, the active region 123, and the second semiconductor region 122 are stacked in that order on the final support substrate 190 when the first semiconductor region 121 is bonded to the final support substrate 190 through the temporary bonding layer 180 (i.e., in the structure of the epitaxial die 100 of the present invention, the initial growth substrate is separated after the final support substrate 190 is bonded)

At this time, one side of the light-emitting part 120 formed on the initial growth substrate may have a shape etched to a predetermined depth (i.e., one side may have a mesa-etched shape), and here, the predetermined depth may refer to a depth up to the second semiconductor region 122, but the present invention is not limited thereto. Meanwhile, the surface of the etched portion of the second semiconductor region 122 of the light-emitting part 120 has gallium (Ga) polarity.

The first ohmic electrode 130 is electrically connected to the first semiconductor region 121 of the light-emitting part 120 and is formed on the first semiconductor region 121 to cover and come into surface contact with an upper surface of the first semiconductor region 121. At this time, the first semiconductor region 121 is electrically connected to the first ohmic electrode 130 through a p-ohmic contact.

The second ohmic electrode 140 is electrically connected to the second semiconductor region 122 of the light-emitting part 120 and is formed at the etched portion on one side of the second semiconductor region 122.

The first ohmic electrode 130 and the second ohmic electrode 140 may each be formed of materials that essentially have high transparency and/or reflectance and excellent electrical conductivity, but the present invention is not limited thereto. The first ohmic electrode 130 may be made of materials including indium tin oxide (ITO), zinc oxide (ZnO), indium zinc oxide (IZO), indium gallium zinc oxide (IGZO), titanium nitride (TiN), Ni(O)—Au, Ni(O)—Ag, and the like. Meanwhile, the materials of the second ohmic electrode 140 may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, which may be used alone or in combination with the above-described metals.

At this time, as described above, the etched portion of the second semiconductor region 122 has a gallium (Ga) polar surface, and the gallium (Ga) polar surface is electrically connected to the second ohmic electrode 140 through an n-ohmic contact.

The passivation layer 150 covers the first ohmic electrode 130 from the etched portion on one side of the light-emitting part 120 via the second ohmic electrode 140, and the other side (i.e., the side opposite to where the second ohmic electrode 140 is formed) of the light-emitting part 120 is partially etched to expose a portion of the first ohmic electrode 130.

The passivation layer 150 may be implemented with electrically insulating materials, and may include, for example, a single layer or multiple layers including at least one material from among silicon oxide, silicon nitride, metallic oxides including Al2O3, and organic insulators.

The contact electrode 160 is electrically connected to the first ohmic electrode 130 and is formed on the first ohmic electrode 130, which is exposed by partially etching the other side (i.e., the side opposite to where the second ohmic electrode 140 is formed) of the passivation layer 150.

The materials of the contact electrode 160 are not limited as long as they have strong adhesion to the first ohmic electrode 130, but may include Ti, TiN, Cr, CrN, V, VN, NiCr, Al, Rh, Pt, Ni, Pd, Ru, Cu, Ag, Au, and the like.

The temporary bonding layer 180 bonds the passivation layer 150, in which the contact electrode 160 is exposed, to the final support substrate 190, and is formed above the passivation layer 150 and the contact electrode 160. Due to the shape of the temporary bonding layer 180 that encloses the contact electrode 160, the contact electrode 160 is interposed between the temporary bonding layer 180 and the first ohmic electrode 130 and thus is not exposed.

The temporary bonding layer 180 may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 190 is bonded to the passivation layer 150 by the temporary bonding layer 180 to support the light-emitting part 120, the first ohmic electrode 130, the second ohmic electrode 140, the passivation layer 150, the contact electrode 160, and the bonding pad layer 170 to be described below, and it is preferable that the final support substrate 190 be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 190 that meet these requirements may include sapphire, which is used for the initial growth substrate, or glass that has been adjusted to have a difference in thermal expansion coefficient of 2 ppm or less from the initial growth substrate.

Meanwhile, in the present invention, the final support substrate 190 functions to support the light-emitting part 120, the first ohmic electrode 130, the second ohmic electrode 140, the passivation layer 150, the contact electrode 160, and the bonding pad layer 170 to be described below after the epitaxial die 100 of the present invention is finally completed. At this time, it is preferable that an LLO sacrificial separation layer (not shown), which is a functional material that can be easily separated and removed by an LLO technique in the process of the third operation S13, which will be described below, be formed between the final support substrate 190 and the temporary bonding layer 180. The above-described LLO sacrificial separation layer (not shown) may be made of materials such as ZnO, ITO, IZO, IGO, IGZO, InGaN, InGaON, GaON, TiN, SiO2, and SiNx.

The bonding pad layer 170 functions as a vertical chip die bonding pad, and is formed on a lower surface of the light-emitting part 120 to be electrically connected to the second ohmic electrode 140. At this time, the bonding pad layer 170 is electrically connected to the second ohmic electrode 140, is exposed to the outside, and functions as a negative electrode.

Meanwhile, a through hole P is formed below the light-emitting part 120 to expose the second ohmic electrode 140, and the bonding pad layer 170 may be electrically connected to the second ohmic electrode 140 through the through hole P.

Meanwhile, it is preferable that the bonding pad layer 170 basically include four regions (not shown).

A first region is an electrode part that forms a p-ohmic contact or n-ohmic contact with the light-emitting part 120, and may include transparent electrically conductive materials (i.e., ITO, IZO, ZnO, IGZO, TiN, and the like) with strong adhesion to the light-emitting part 120.

A second region is a highly reflective region, and may include highly reflective materials (i.e., Al, Ag, AgCu, Rh, Pt, Ni, Pd, and the like).

A third region is a diffusion barrier layer, which is a material layer introduced to prevent low melting point metals forming the bonding pad layer 170 in a fourth region to be described below from diffusing toward the light-emitting part 120 during or after the process, and may include high melting point metals (e.g., Cr, V, Ti, W, Mo, and Re), or metals with high atomic packing density (e.g., Pt and Ni).

A fourth region is a die bonding layer that bonds with the first upper electrode pad 11a, and may be formed of low melting point metals and noble metals such as gold (Au), silver (Ag), copper (Cu), and palladium (Pd), but the present invention is not limited thereto. In addition, the low melting point metals of the bonding pad layer 170 may be formed of metals such as In, Sn, Zn, and Pb alone or alloys including these metals.

Furthermore, although not shown in the drawing, before the bonding pad layer 170 is formed on the lower surface of the light-emitting part 120, a surface texture pattern with a predetermined shape or an irregular shape may be formed on a lower surface of the second semiconductor region 122 to extract as much light generated in the active region 123 into the air as possible.

Accordingly, the epitaxial die 100 according to the first embodiment of the present invention has a form in which the contact electrode 160, which is a positive electrode, and the first ohmic electrode 130 are interposed between the temporary bonding layer 180 and the light-emitting part 120 and thus are not exposed, and only the bonding pad layer 170, which functions as a negative electrode, is exposed to the outside.

The second operation S12 is an operation of placing the epitaxial die 100 on the first upper electrode pad 11a, which is a common electrode, and electrically connecting the first upper electrode pad 11a and the bonding pad layer 170 by bonding them through a bonding layer 12. At this time, the placement and bonding of the epitaxial die 100 can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, the first upper electrode pad 11a is provided as a common electrode rather than an individual electrode because it is advantageous in the transfer process, and in the process of dividing the region of the epitaxial die in the fourth operation S14 to be described below, when the first upper electrode pad 11a is a common positive electrode, the light-emitting part 120 must be etched to the extent that the light-emitting part 120 is completely isolated into separate parts (full isolation). On the other hand, when the first upper electrode pad 11a is a common negative electrode, it is sufficient to partially isolate the light-emitting part 120 (semi-isolation), for example, by etching the epitaxial die only up to a portion of the second semiconductor region 122 using the MESA process, which provides a processing advantage.

Meanwhile, when it is necessary to achieve objectives such as (1) high precision placement of an epitaxial die 100, (2) an epitaxial die 100 with an ultra-small size of less than 50 μm×50 μm, and (3) an epitaxial die 100 having a self-assembly structure, additional masking media (such as a photoresist, ceramics (like glass, quartz, and alumina), or an invar fine metal mask (FMM)) or processes may be employed before the placement and bonding of the epitaxial die 100.

The third operation S13 is an operation of separating the final support substrate 190 of the epitaxial die 100. At this time, in the third operation S13, the final support substrate 190 may be separated from the temporary bonding layer 180 using an LLO technique. Here, the LLO technique is a technique of separating the final support substrate 190 from the temporary bonding layer 180 by irradiating a rear surface of the transparent final support substrate 190 with an ultraviolet (UV) laser beam having a uniform output and beam profile, and a single wavelength.

The fourth operation S14 is an operation of etching and removing the temporary bonding layer 180, dividing the epitaxial die 100 into a plurality of regions so that each region provides a different color wavelength, and exposing the contact electrode 160 of each divided region.

At this time, in the fourth operation S14, the epitaxial die 100 may be divided into a plurality of regions by etching the epitaxial die 100 to the extent that the light-emitting part 120 is fully isolated into separate parts (full isolation) or by etching the epitaxial die 100 only up to a portion of the second semiconductor region 122 using the MESA process. Further, in the fourth operation S14, the epitaxial die 100 may be divided into three regions A1, A2, and A3 so that the epitaxial die 100 emits three types of light, such as blue, green, and red light, but the present invention is not limited thereto, and the epitaxial die 100 may be divided into a greater number of regions. For example, in the fourth operation S14, according to the design, the epitaxial die 100 may be divided into six regions, forming two pixels that emit each of blue, green, and red light. In this case, when one pixel is defective, the other pixel can replace the defective pixel, thereby providing the advantage of redundancy to maintain functionality despite defects.

Meanwhile, as shown in FIGS. 6 and 7, the epitaxial die 100 according to the first embodiment of the present invention may include an etching stop layer E between the light-emitting part 120 and the bonding pad layer 170 to prevent the bonding pad layer 170 from being etched.

That is, in the fourth operation S14, when the epitaxial die 100 is divided into a plurality of regions and the light-emitting part 120 is etched to the extent of being completely isolated (full isolation), a portion of the bonding pad layer 170, which contains metal components and is located along the division boundary, may also be etched and then redeposited, which may cause defects in the device.

Accordingly, the epitaxial die 100 of the present invention has a window or window frame shape and includes the etching stop layer E disposed along the division boundary to prevent the bonding pad layer 170 from being etched at the division boundary. The etching stop layer E may be formed of SiO2, SiNx, dielectric materials, or the like.

Further, in the fourth operation S14, after removing the temporary bonding layer 180 and dividing the epitaxial die 100 into a plurality of regions, a mold part 14 surrounding the epitaxial die 100 may be formed, and then a portion of the mold part 14 may be etched to expose the contact electrode 160. At this time, the mold part 14 may be made of materials that enable LDS or LDI, allowing laser drilling in the fifth operation S15 to be described below.

Meanwhile, before the extension electrode is formed in the fourth operation S14 or the fifth operation S15, electrical defects of the epitaxial die 100 may be inspected through the exposed contact electrode 160, and the semiconductor light-emitting device may be repaired by replacing the corresponding epitaxial die 100 when the electrical defect inspection result indicates that the epitaxial die 100 is electrically defective. That is, in the present invention, electrical defects in the epitaxial die 100 can be detected and the defective epitaxial die 100 can be easily replaced before an upper wiring process is performed to form an extension electrode 13.

The fifth operation S15 is an operation of forming the extension electrode 13 that electrically connects the second upper electrode pad 11b, which is an individual electrode, and the exposed contact electrode 160.

More specifically, in the fifth operation S15, laser drilling is used to etch the mold part 14 above a plurality of second upper electrode pads 11b to form the through hole H, and then the extension electrode 13 is formed to extend vertically from an upper portion of each of the plurality of second upper electrode pads 11b through the through hole H to above the mold part 14 and then be bent toward the contact electrode 160 of each of the divided regions of the epitaxial die 100, thereby electrically connecting the contact electrodes 160 of the divided regions to the plurality of second upper electrode pads 11b. Meanwhile, when the contact electrode 160 is covered by the mold part 14, the mold part 14 may be partially etched to expose the contact electrode 160.

The sixth operation S16 is an operation of forming a black matrix 15 that covers the extension electrode 13 and the mold part 14, and forming a color conversion layer 16 above each divided region of the epitaxial die 100, so that each divided region of the epitaxial die 100 emits light of a different wavelength.

The black matrix 15 may be formed using photolithography and spin coating processes, but the present invention is not limited thereto. In addition, the black matrix 15 may be formed of a metal thin film or a carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a block copolymer resin with pigment-affinity groups such as amino, hydroxyl, and carboxyl groups, with carbon black as a medium, and mixing the blend with a solvent and a dispersing agent).

In addition, the color conversion layer 16, or a phosphor layer, provides light in a second wavelength range when light in a first wavelength range emitted from the light-emitting part 120 is incident thereon, and the color conversion layer 16 is disposed above each divided region of the epitaxial die 100 to allow each divided region to emit light in a different wavelength range. For example, when blue or ultraviolet light is incident from the light-emitting part 120, the color conversion layer 16 can emit light in a green or red wavelength range. Meanwhile, the wavelength range of light emitted from the light-emitting part 120 and the wavelength range of light provided by the color conversion layer 16 may be varied according to the design.

The above-described color conversion layer 16 may include quantum dot (QD) nanoparticles, such as InP, GaP, ZnS, ZnSeS, CdSe, CdS, and Perovskite, blue phosphor particles, such as CaMgSi2O6:Eu2+ and BaO—MgO—Al2O3, green and red phosphor particles composed of silicon oxide, aluminum oxide, and silicon nitride, or red phosphor particles such as KSF(K2SiF6:Mn4+) and KGF(K2GeF6:Mn4+).

In addition, although not shown in the drawing, a color filter layer known in the display industry can be separately provided after the color conversion layer 16 is formed to improve color purity.

Furthermore, although not shown in the drawing, a transparent organic protection layer may be additionally provided to protect the color conversion layer 16 and the color filter layer from the ambient environment.

[symbol]

Hereinafter, with reference to the accompanying drawings, a method (S20) of manufacturing a semiconductor light-emitting device employing a color conversion technique according to a second embodiment of the present invention will be described in detail.

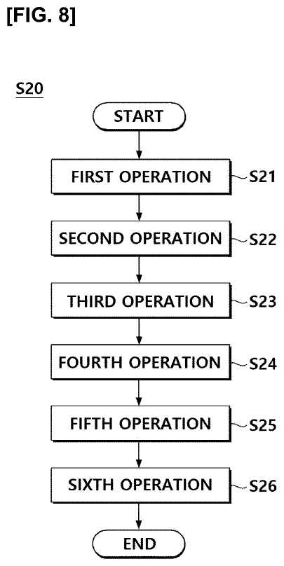

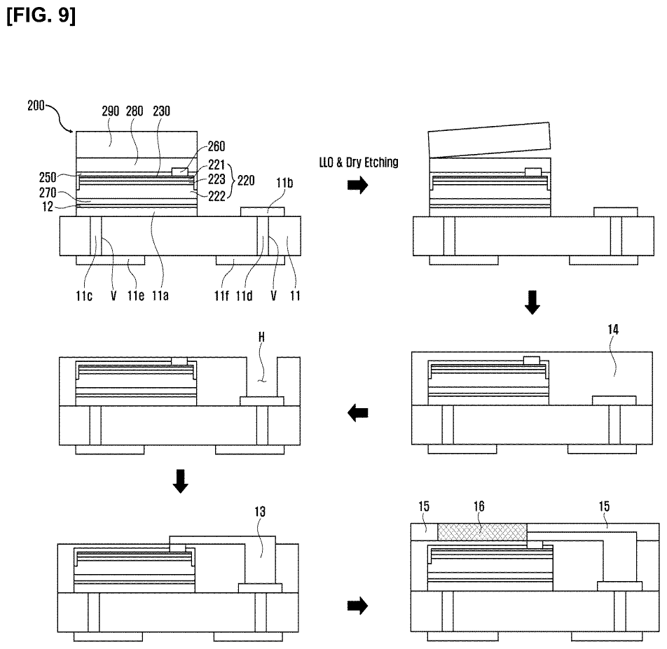

FIG. 8 is a flowchart of the method of manufacturing the semiconductor light-emitting device employing a color conversion technique according to the second embodiment of the present invention, and FIG. 9 illustrates a process of manufacturing the semiconductor light-emitting device employing a color conversion technique according to the second embodiment of the present invention.

As shown in FIGS. 8 and 9, the method (S20) of manufacturing the semiconductor light-emitting device employing a color conversion technique according to the second embodiment of the present invention includes a first operation S21, a second operation S22, a third operation S23, a fourth operation S24, a fifth operation S25, and a sixth operation S26. However, it is of course possible to change the order of the processes shown in FIGS. 8 and 9.

The first operation S21 is an operation of preparing an epitaxial die 200 according to the second embodiment of the present invention and a substrate part 11.

The epitaxial die 200 according to the second embodiment of the present invention includes a light-emitting part 220 that generates light, a first ohmic electrode 230, a passivation layer 250, a contact electrode 260 that is not exposed to the outside, a bonding pad layer 270 exposed to the outside, a temporary bonding layer 280, and a final support substrate 290.

The light-emitting part 220 generates light, and details of a first semiconductor region 221, a second semiconductor region 222, and an active region 223 are the same as those of the above-described method (S10) of manufacturing the semiconductor light-emitting device using the epitaxial die according to the first embodiment of the present invention, and thus redundant descriptions will be omitted (the structure of the epitaxial die 200 of the present invention is in a state in which an initial growth substrate is separated after the final support substrate 290 has been bonded).

Meanwhile, the light-emitting part 220, which is epitaxially grown on the initial growth substrate in the order of the second semiconductor region 222, the active region 223, and the first semiconductor region 221, has a structure in which the first semiconductor region 221, the active region 223, and the second semiconductor region 222 are stacked in that order on the final support substrate 290 when the first semiconductor region 221 is bonded to the final support substrate 290 through the temporary bonding layer 280.

At this time, both sides of the light-emitting part 220 formed on the initial growth substrate may have a shape etched to a predetermined depth, and here, the predetermined depth may refer to a depth up to the second semiconductor region 222, but the present invention is not limited thereto.

The first ohmic electrode 230 is electrically connected to the first semiconductor region 221 of the light-emitting part 220 and is formed on the first semiconductor region 221 to cover and come into surface contact with an upper surface of the first semiconductor region 221. At this time, the first semiconductor region 221 is electrically connected to the first ohmic electrode 230 through a p-ohmic contact.

This first ohmic electrode 230 may be basically formed of a material with high transparency and excellent electrical conductivity, but the present invention is not limited thereto. The first ohmic electrode 230 may be made of optically transparent materials such as indium tin oxide (ITO), zinc oxide (ZnO), indium zinc oxide (IZO), indium gallium zinc oxide (IGZO), titanium nitride (TiN), Ni(O)—Au, Ni(O)—Ag, and the like.

The passivation layer 250 covers the first ohmic electrode 230 from the etched portions on both sides of the light-emitting part 220, and is partially etched to expose a portion of the first ohmic electrode 230.

The passivation layer 250 may be implemented with electrically insulating materials, and may include, for example, a single layer or multiple layers including at least one material from among silicon oxide, silicon nitride, metallic oxides including Al2O3, and organic insulators.

The contact electrode 260 is electrically connected to the first ohmic electrode 230 and is formed on the first ohmic electrode 230 exposed by etching a portion of the passivation layer 250.

The materials of the contact electrode 260 are not limited as long as they have strong adhesion to the first ohmic electrode 230, but may include Ti, TiN, Cr, CrN, V, VN, NiCr, Al, Rh, Pt, Ni, Pd, Ru, Cu, Ag, Au, and the like.

The temporary bonding layer 280 bonds the passivation layer 250, in which the contact electrode 260 is exposed, to the final support substrate 290, and is formed above the passivation layer 250 and the contact electrode 260. Due to the shape of the temporary bonding layer 280 that encloses the contact electrode 260, the contact electrode 260 is interposed between the temporary bonding layer 280 and the first ohmic electrode 230 and thus is not exposed.

The temporary bonding layer 280 may include materials such as benzocyclobutene (BCB), SU-8 polymer, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The final support substrate 290 is bonded to the passivation layer 250 by the temporary bonding layer 280 to support the light-emitting part 220, the first ohmic electrode 230, the passivation layer 250, the contact electrode 260, and the bonding pad layer 270 to be described below, and it is preferable that the final support substrate 290 be formed of a material that has a thermal expansion coefficient equal or similar to that of the initial growth substrate, and be simultaneously optically transparent, as long as the difference in thermal expansion coefficient does not exceed 2 ppm. The most preferable materials for the final support substrate 290 that meet these requirements may include sapphire, which is used for the initial growth substrate, or glass that has been adjusted to have a difference in thermal expansion coefficient of 2 ppm or less from the initial growth substrate.

Meanwhile, in the present invention, the final support substrate 290 functions as a final support substrate that supports the light-emitting part 220, the first ohmic electrode 230, the passivation layer 250, the contact electrode 260, and the bonding pad layer 270 to be described below after the epitaxial die 200 of the present invention is finally completed. At this time, it is preferable that an LLO sacrificial separation layer (not shown), which is a functional material that can be easily separated and removed by an LLO technique in the process of the third operation S23, be formed between the final support substrate 290 and the temporary bonding layer 280. The above-described LLO sacrificial separation layer (not shown) may be made of materials such as ZnO, ITO, IZO, IGO, IGZO, InGaN, InGaON, GaON, TiN, SiO2, and SiNx.

The bonding pad layer 270 functions as a vertical chip die bonding pad, and is formed on a lower surface of the light-emitting part 220 to be electrically connected to the light-emitting part 220. At this time, the lower surface of the light-emitting part 220 has a nitrogen (N) polar surface, and the bonding pad layer 270 is electrically connected to the nitrogen (N) polar surface through an n-ohmic contact, is exposed to the outside, and functions as a negative electrode as well as an active reflector.

Meanwhile, it is preferable that the bonding pad layer 170 basically include four regions (not shown).

A first region is an electrode part that forms a p-ohmic contact or n-ohmic contact with the light-emitting part 120, and may include transparent electrically conductive materials (i.e., ITO, IZO, ZnO, IGZO, TiN, and the like) with strong adhesion to the light-emitting part 120.

A second region is a highly reflective region, and may include highly reflective materials (i.e., Al, Ag, AgCu, Rh, Pt, Ni, Pd, and the like).

A third region is a diffusion barrier layer, which is a layer of material introduced to prevent the low melting point metals forming the bonding pad layer 170 of the fourth region that will be described below from diffusing toward the light emitting part 120 during or after the process, and may include high melting point metals (Cr, V, Ti, W, Mo, Re) or metals with high atomic filling (Pt, Ni).

A fourth region is a die bonding layer that bonds with the first upper electrode pad 11a, and may be formed of low melting point metals and noble metals such as gold (Au), silver (Ag), copper (Cu), and palladium (Pd), but the present invention is not limited thereto. In addition, the low melting point metals of the bonding pad layer 170 may be formed of metals such as In, Sn, Zn, and Pb alone or alloys including these metals.

Furthermore, although not shown in the drawing, before the bonding pad layer 270 is formed on the lower surface of the light-emitting part 220, a surface texture pattern with a predetermined shape or an irregular shape may be formed on a lower surface of the second semiconductor region 222 to extract as much light generated in the active region 223 into the air as possible.

Accordingly, the epitaxial die 200 according to the second embodiment of the present invention has a form in which the contact electrode 260, which is a positive electrode, and the first ohmic electrode 230 are interposed between the temporary bonding layer 280 and the light-emitting part 220 and thus are not exposed, and only the bonding pad layer 270, which functions as a negative electrode, is exposed to the outside.

Meanwhile, details of the substrate part 11 are the same as those of the method (S10) of manufacturing the semiconductor device employing a color conversion technique according to the first embodiment of the present invention described above, and thus redundant descriptions will be omitted.

In addition, undescribed details of the second to sixth operations S22 to S26 are the same as those of the method (S10) of manufacturing the semiconductor device employing a color conversion technique according to the first embodiment of the present invention described above, and thus redundant descriptions will be omitted.

[symbol]

Hereinafter, with reference to the accompanying drawings, a method (S30) of manufacturing a semiconductor light-emitting device employing a color conversion technique, according to a third embodiment of the present invention will be described in detail.

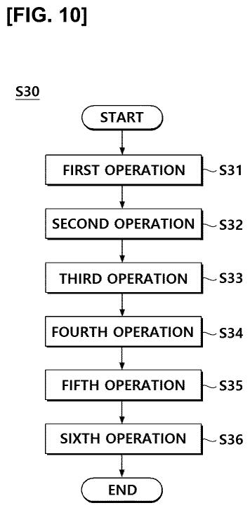

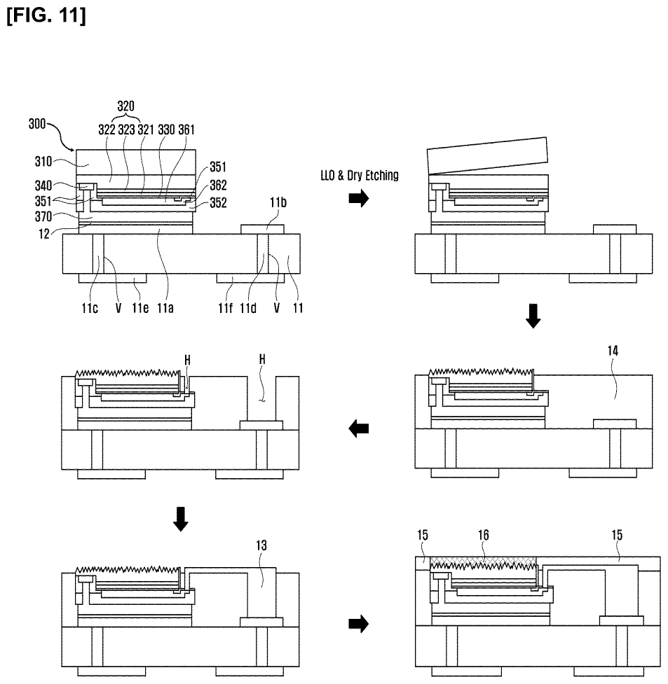

FIG. 10 is a flowchart of the method of manufacturing the semiconductor light-emitting device employing a color conversion technique according to the third embodiment of the present invention, and FIG. 11 illustrates a process of manufacturing the semiconductor light-emitting device employing a color conversion technique according to the third embodiment of the present invention.

As shown in FIGS. 10 and 11, the method (S30) of manufacturing the semiconductor light-emitting device employing a color conversion technique according to the third embodiment of the present invention includes a first operation S31, a second operation S32, a third operation S33, a fourth operation S34, a fifth operation S35, and a sixth operation S36. However, it is of course possible to change the order of the processes shown in FIGS. 10 and 11.

The first operation S31 is an operation of preparing an epitaxial die 300 according to the third embodiment of the present invention and a substrate part 11.

The epitaxial die 300 according to the third embodiment of the present invention includes a final support substrate 310, a light-emitting part 320 that generates light, a first ohmic electrode 330, a second ohmic electrode 340, a first passivation layer 351, a contact electrode 360 that is not exposed to the outside, a second passivation layer 352, and a bonding pad layer 370 that is exposed to the outside.

The final support substrate 310 supports the light-emitting part 320, the first ohmic electrode 330, the second ohmic electrode 340, the first passivation layer 351, the contact electrode 360, the second passivation layer 352, and the bonding pad layer 370, and a sapphire initial growth substrate may be used thereas. The light-emitting part 320 to be described below may be epitaxially grown on the final support substrate 310.

Meanwhile, in the present invention, the final support substrate 310, which supports the light-emitting part 320, the first ohmic electrode 330, the second ohmic electrode 340, the first passivation layer 351, the contact electrode 360, the second passivation layer 352, and the bonding pad layer 370, is an initial growth substrate on which the light-emitting part 320 is grown.

The light-emitting part 320 generates light, and details of a first semiconductor region 321, a second semiconductor region 322, and an active region 323 are the same as those of the above-described method (S10) of manufacturing the semiconductor light-emitting device using the epitaxial die according to the first embodiment of the present invention, and thus redundant descriptions will be omitted.

At this time, one side of the light-emitting part 320 formed on the final support substrate 310 may have a shape etched to a predetermined depth (i.e., one side may have a mesa-etched shape), and here, the predetermined depth may refer to a depth up to the second semiconductor region 322, but the present invention is not limited thereto. Meanwhile, the surface of the etched portion of the second semiconductor region 322 of the light-emitting part 320 has gallium (Ga) polarity.

The first ohmic electrode 330 is electrically connected to the first semiconductor region 321 of the light-emitting part 320 and is formed on the first semiconductor region 321 to cover and come into surface contact with an upper surface of the first semiconductor region 321. At this time, the first semiconductor region 321 is electrically connected to the first ohmic electrode 330 through a p-ohmic contact.

The second ohmic electrode 340 is electrically connected to the second semiconductor region 322 of the light-emitting part 320 and is formed at the etched portion on one side of the second semiconductor region 322.

The first ohmic electrode 330 and the second ohmic electrode 340 may be formed of materials that essentially have high transparency and/or reflectance and excellent electrical conductivity, but the present invention is not limited thereto. The materials of the first ohmic electrode 330 may include optically transparent materials such as indium tin oxide (ITO), zinc oxide (ZnO), indium zinc oxide (IZO), indium gallium zinc oxide (IGZO), and titanium nitride (TiN), and optically reflective materials such as Ag, Al, Rh, Pt, Ni, Pd, Ru, Cu, and Au may be used alone or in combination with the above-described optically transparent materials. Meanwhile, the materials of the second ohmic electrode 340 may include optically transparent materials such as indium tin oxide (ITO), zinc oxide (ZnO), indium zinc oxide (IZO), indium gallium zinc oxide (IGZO), and titanium nitride (TiN), and metals such as Cr, Ti, Al, V, W, Re, and Au, and may be used alone or in combination with the above-described metals.

At this time, as described above, the etched portion of the second semiconductor region 322 has a gallium (Ga) polar surface, and the gallium (Ga) polar surface is electrically connected to the second ohmic electrode 340 through an n-ohmic contact.

The first passivation layer 351 covers one side of the first ohmic electrode 330 from the etched portion on one side of the light-emitting part 320 via the second ohmic electrode 340, and covers the other side of the first ohmic electrode 330 from the other side of the light-emitting part 320. The first passivation layer 351 may have a shape that covers one side and the other side of the first ohmic electrode 330 and may thus have a shape that exposes a portion of the first ohmic electrode.

The first passivation layer 351 may be implemented with electrically insulating materials, and may include, for example, a single layer or multiple layers including at least one material from among silicon oxide, silicon nitride, metallic oxides including Al2O3, and organic insulators.

The contact electrode 360 is electrically connected to the first ohmic electrode 330 and formed on the first ohmic electrode 330 exposed between gaps in the first passivation layer 351. The contact electrode 360 includes a base part 361 and an extension part 362 that is formed to extend from an end portion of the base part 361 to the other side (i.e., the side opposite to where the second ohmic electrode 340 is formed) of the light-emitting part 320 and is placed between the first passivation layer 351 and the second passivation layer 352. At this time, the extension part 362 may be formed to be stepped by being partially bent.

The materials of the contact electrode 360 are not limited as long as they have strong adhesion to the first ohmic electrode 330, but may include Ti, TiN, Cr, CrN, V, VN, NiCr, Al, Rh, Pt, Ni, Pd, Ru, Cu, Ag, Au, and the like.

The second passivation layer 352 covers the first passivation layer 351 and the contact electrode 360, and here, an end portion on the other side (i.e., the side opposite to where the second ohmic electrode 340 is formed) of the contact electrode 360 may be partially etched, and the second passivation layer 352 may cover an end portion on one side of the contact electrode 360 from the etched end portion on the other side of the contact electrode 360 via the contact electrode 360 to prevent the contact electrode 360 from being exposed to the outside. Due to the shape of the second passivation layer 352 that encloses the contact electrode 360 in this manner, the contact electrode 360 is interposed between the second passivation layer 352 and the first ohmic electrode 330 and thus is not exposed.

The second passivation layer 352 may be implemented with electrically insulating materials, and may include, for example, a single layer or multiple layers including at least one material from among silicon oxide, silicon nitride, metallic oxides including Al2O3, and organic insulators.

The bonding pad layer 370 functions as a vertical chip die bonding pad, and is formed on the second passivation layer 352 to be electrically connected to the second ohmic electrode 340. At this time, the bonding pad layer 370 is electrically connected to the second ohmic electrode 340, is exposed to the outside, and functions as a negative electrode.

Meanwhile, a first through hole P1 is formed in the first passivation layer 351 above the second ohmic electrode 340 to expose the second ohmic electrode 340, and a second through hole P2 in communication with the first through hole P2 is formed in the second passivation layer 352. The bonding pad layer 370 may be electrically connected to the second ohmic electrode 340 through the first through hole P1 and the second through hole P2.

The bonding pad layer 370 may include a diffusion barrier layer made of high melting point metals (such as Cr, V, Ti, W, Mo, and Re), or metals with high atomic packing density (such as Pt and Ni). In addition, for die bonding, the bonding pad layer 370 may basically include low melting point metals and noble metals such as gold (Au), silver (Ag), copper (Cu), and palladium (Pd), but the present invention is not limited thereto. In addition, the low melting point metals of the bonding pad layer 370 may be formed of metals such as In, Sn, Zn, and Pb alone or alloys including these metals.

Accordingly, the epitaxial die 300 according to the third embodiment of the present invention has a form in which the contact electrode 360, which is a positive electrode, and the first ohmic electrode 330 are interposed between the second passivation layer 352 and the light-emitting part 320 and thus are not exposed, and only the bonding pad layer 370, which functions as a negative electrode, is exposed to the outside.

Meanwhile, details of the substrate part 11 are the same as those of the method (S10) of manufacturing the semiconductor device employing a color conversion technique according to the first embodiment of the present invention described above, and thus redundant descriptions will be omitted.

The second operation S32 is an operation of placing the epitaxial die 300 upside down on a first upper electrode pad 11a, and electrically connecting the first upper electrode pad 11a and the bonding pad layer 370 by bonding them through a bonding layer 12.

The third operation S33 is an operation of separating the final support substrate 310 of the epitaxial die 300.

The fourth operation S34 is an operation of etching the epitaxial die 300 to divide the epitaxial die 300 into a plurality of regions, etching the other side of the light-emitting part 320 (i.e., the side opposite to where the second ohmic electrode 340 is formed) so that the first passivation layer 351 is exposed, and exposing the extension part 362 of the contact electrode 360, which is not exposed, by etching the exposed first passivation layer 351. At this time, a passivation layer may be additionally formed on the etched and exposed side surface of the light-emitting part 320.

At this time, in the fourth operation S34, the epitaxial die 300 may be divided into a plurality of regions by etching the epitaxial die 300 to the extent that the light-emitting part 320 is fully isolated into separate parts (full isolation), or by etching the epitaxial die 300 only up to a portion of the light-emitting part 320 using the MESA process. Further, in the fourth operation S34, the epitaxial die 300 may be divided into three regions so that the epitaxial die 300 emits three types of light, such as blue, green, and red light, but the present invention is not limited thereto, and the epitaxial die 300 may be divided into a greater number of regions. For example, in the fourth operation S34, according to the design, the epitaxial die 300 may be divided into six regions, which form two pixels emitting each of blue, green, and red light. In this case, when one pixel is defective, the other pixel can replace the defective pixel, thereby providing the advantage of redundancy to maintain functionality despite defects.

Meanwhile, in the fourth operation S34, a surface texture pattern of a predetermined shape or an irregular shape may be formed on an upper surface of the light-emitting part 320, i.e., the upper surface of the second semiconductor region 322, of the upside-down epitaxial die 300 to extract as much light generated in the active region 323 into the air as possible.

The fifth operation S35 is an operation of forming an extension electrode 13 that electrically connects a second upper electrode pad 11b and the contact electrode 360. More specifically, in the fifth operation S35, laser drilling is used to etch a mold part 14 above the second upper electrode pad 11b to form a through hole H above the second upper electrode pad 11b, and when necessary, the mold part 14 above the extension part 362 of the contact electrode 360 is etched to form a through hole H above the extension part 362 of the contact electrode 360.

Subsequently, in the fifth operation S35, the extension electrode 13 that electrically connects the second upper electrode pad 11b and the exposed extension part 362 of the contact electrode 360 is formed, and the extension electrode 13 may have a shape formed to extend vertically from an upper portion of the second upper electrode pad 11b to above the mold part 14 through the through hole H, then be bent and extend laterally toward the contact electrode 360, and finally be bent vertically to extend toward and come into contact with the exposed contact electrode 360. Meanwhile, when the contact electrode 360 is covered by the mold part 14, the mold part 14 may be partially etched to expose the contact electrode 360.

Meanwhile, undescribed details of the second to sixth operations S32 to S36 are the same as those of the method (S10) of manufacturing the semiconductor device employing a color conversion technique according to the first embodiment of the present invention described above, and thus redundant descriptions will be omitted.

Hereinafter, with reference to the accompanying drawings, a method (S40) of manufacturing a semiconductor light-emitting device employing a color conversion technique according to a fourth embodiment of the present invention will be described in detail.

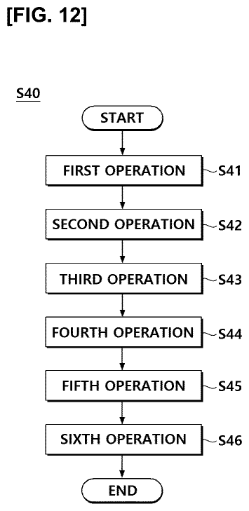

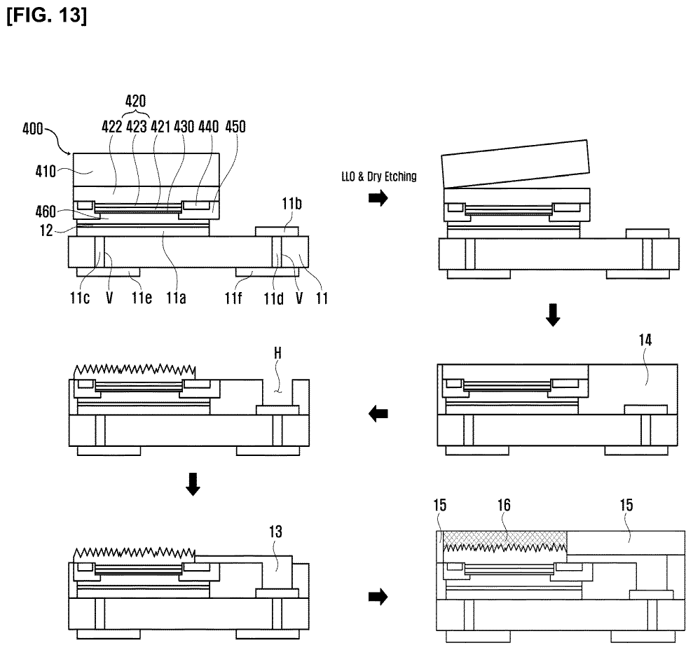

FIG. 12 is a flowchart of the method of manufacturing the semiconductor light-emitting device employing a color conversion technique according to the fourth embodiment of the present invention, and FIG. 13 illustrates a process of manufacturing the semiconductor light-emitting device employing a color conversion technique according to the fourth embodiment of the present invention.

As shown in FIGS. 12 and 13, the method (S40) of manufacturing the semiconductor light-emitting device employing a color conversion technique according to the fourth embodiment of the present invention includes a first operation S41, a second operation S42, a third operation S43, a fourth operation S44, a fifth operation S45, and a sixth operation S46. However, it is of course possible to change the order of the processes shown in FIGS. 12 and 13.

The first operation S41 is an operation of preparing an epitaxial die 400 according to the fourth embodiment of the present invention and a substrate part 11.

The epitaxial die 400 according to the fourth embodiment of the present invention includes a final support substrate 410, a light-emitting part 420 that generates light, a first ohmic electrode 430, a contact electrode 440 that is not exposed to the outside, a passivation layer 450, and a bonding pad layer 460 that is exposed to the outside.

The final support substrate 410 supports the light-emitting part 420, the first ohmic electrode 430, a contact electrode 440, the passivation layer 450, and the bonding pad layer 460, and a sapphire initial growth substrate may be used thereas. The light-emitting part 420 to be described below may be epitaxially grown on the final support substrate 410.

Meanwhile, in the present invention, the final support substrate 410 that supports the light-emitting part 420, the first ohmic electrode 430, the contact electrode 440, the passivation layer 450, and the bonding pad layer 460 is an initial growth substrate on which the light-emitting part 420 is grown.

The light-emitting part 420 generates light, and details of a first semiconductor region 421, a second semiconductor region 422, and an active region 423 are the same as those of the above-described method (S10) of manufacturing the semiconductor light-emitting device using the epitaxial die according to the first embodiment of the present invention, and thus redundant descriptions will be omitted.

At this time, the light-emitting part 420 formed on the final support substrate 410 may have a side portion, i.e., one or both sides, each etched to a predetermined depth (i.e., both side surfaces may have a mesa-etched shape), and when viewed from above, all of upper, lower, left, and right edges may have a mesa-etched shape. Here, the predetermined depth may refer to a depth up to the second semiconductor region 422, but the present invention is not limited thereto. Meanwhile, the surface of the etched portion of the second semiconductor region 422 of the light-emitting part 420 has gallium (Ga) polarity.

The first ohmic electrode 430 is electrically connected to the first semiconductor region 421 of the light-emitting part 420 and is formed on the first semiconductor region 421 to cover and come into surface contact with an upper surface of the first semiconductor region 421. At this time, the first semiconductor region 421 is electrically connected to the first ohmic electrode 430 through a p-ohmic contact.

The contact electrode 440 is electrically connected to the second semiconductor region 422 of the light-emitting part 420, and may be formed at the etched side portion, i.e., one side or both sides, of the second semiconductor region 422.

The first ohmic electrode 430 and the contact electrode 440 may be basically formed of materials that have high transparency or reflectance and excellent electrical conductivity, but the present invention is not limited thereto. The materials of the first ohmic electrode 430 may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination.

Meanwhile, the materials of the contact electrode 440 may include optically transparent materials such as indium tin oxide (ITO), ZnO, indium zinc oxide (IZO), indium gallium zinc oxide (IGZO), and titanium nitride (TiN), and metals such as Cr, Ti, Al, V, W, Re, and Au, which may be used alone or in combination.

At this time, as described above, the etched portion of the second semiconductor region 422 has a gallium (Ga) polar surface, and the gallium (Ga) polar surface is electrically connected to the contact electrode 440 through an n-ohmic contact.

The passivation layer 450 covers a side portion of the first ohmic electrode 430 from the etched portion of the light-emitting part 420 via the contact electrode 440, and when both sides of the light-emitting part 420 are etched, the passivation layer 450 may have a shape that covers one side of the first ohmic electrode 430 from the etched portion on one side of the light-emitting part 420 via the contact electrode 440, and covers the other side of the first ohmic electrode 430 from the etched portion on the other side of the light-emitting part 420 via the contact electrode 440. Due to such a shape of the passivation layer 450, the contact electrode 440 is interposed between the passivation layer 450 and the light-emitting part 420 and thus is not exposed.

The passivation layer 450 may be implemented with electrically insulating materials, and may include, for example, a single layer or multiple layers including at least one material from among silicon oxide, silicon nitride, metallic oxides including Al2O₃, and organic insulators.

The bonding pad layer 460 functions as a vertical chip die bonding pad, and is formed on the first ohmic electrode 430 and the passivation layer 450 to be electrically connected to the first ohmic electrode 430. At this time, the bonding pad layer 460 is electrically connected to the first ohmic electrode 430 through a p-ohmic contact and is exposed to the outside, thereby functioning as a positive electrode.

The bonding pad layer 460 may include a diffusion barrier layer made of high melting point metals (such as Cr, V, Ti, W, Mo, and Re), or metals with high atomic packing density (such as Pt and Ni), and may basically include low melting point metals and noble metals such as gold (Au), silver (Ag), copper (Cu), and palladium (Pd), but the present invention is not limited thereto. In addition, the low melting point metals of the bonding pad layer 460 may be formed of metals such as In, Sn, Zn, and Pb alone or alloys including these metals.

Accordingly, the epitaxial die 400 according to the fourth embodiment of the present invention has a form in which the contact electrode 440, which is a negative electrode, is interposed between the passivation layer 450 and the light-emitting part 420 and thus is not exposed, and only the bonding pad layer 460, which functions as a positive electrode, is exposed to the outside.

Meanwhile, details of the substrate part 11 are the same as those of the method (S10) of manufacturing the semiconductor device employing a color conversion technique according to the first embodiment of the present invention described above, and thus redundant descriptions will be omitted.

The second operation S42 is an operation of placing the epitaxial die 400 upside down on a first upper electrode pad 11a, and electrically connecting the first upper electrode pad 11a and the bonding pad layer 460 by bonding them through a bonding layer 12.

The third operation S43 is an operation of separating the final support substrate 410 of the epitaxial die 400.

The fourth operation S44 is an operation of etching the epitaxial die 400 into a plurality of regions, and etching one side of the light-emitting part 420 to expose the contact electrode 440. That is, the fourth operation S44 is an operation of etching one side of the second semiconductor region 422 through dry etching or wet etching to expose the contact electrode 440, which is interposed between the second semiconductor region 422 and the passivation layer 450 and is not exposed.

At this time, in the fourth operation S44, the epitaxial die 400 may be divided into a plurality of regions by etching the epitaxial die 400 to the extent that the light-emitting part 420 is fully isolated into separate parts (full isolation), or by etching the epitaxial die 400 only up to a portion of the light-emitting part 420 using the MESA process. Further, in the fourth operation S34, the epitaxial die 400 may be divided into three regions so that the epitaxial die 400 emits three types of light, such as blue, green, and red light, but the present invention is not limited thereto, and the epitaxial die 400 may be divided into a greater number of regions. For example, in the fourth operation S44, according to the design, the epitaxial die 400 may be divided into six regions, which form two pixels emitting each of blue, green, and red light. In this case, when one pixel is defective, the other pixel can replace the defective pixel, thereby providing the advantage of redundancy to maintain functionality despite defects.

Meanwhile, in the fourth operation S44, a surface texture pattern of a predetermined shape or an irregular shape may be formed on an upper surface of the light-emitting part 420, i.e., the upper surface of the second semiconductor region 422, of the upside-down epitaxial die 400 to extract as much light generated in the active region 423 into the air as possible.

The fifth operation S45 is an operation of forming an extension electrode 13 that electrically connects a second upper electrode pad 11b and the contact electrode 440. More specifically, in the fifth operation S45, laser drilling is used to etch a mold part 14 above the second upper electrode pad 11b to form a through hole H, and the extension electrode 13 is formed to extend vertically from an upper portion of the second upper electrode pad 11b to above the mold part 14 through the through hole H and then be bent toward the contact electrode 440, thereby electrically connecting the contact electrode 440 and the second upper electrode pad 11b.

Meanwhile, undescribed details of the second to sixth operations S42 to S46 are the same as those of the method (S10) of manufacturing the semiconductor device employing a color conversion technique according to the first embodiment of the present invention described above, and thus redundant descriptions will be omitted.

Hereinafter, with reference to the accompanying drawings, a method (S50) of manufacturing a semiconductor light-emitting device employing a color conversion technique, according to a fifth embodiment of the present invention will be described in detail.

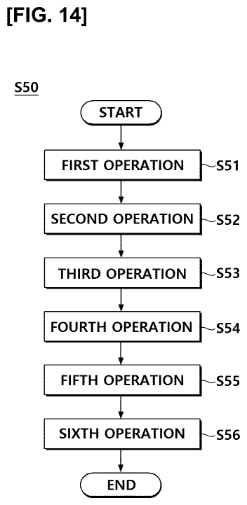

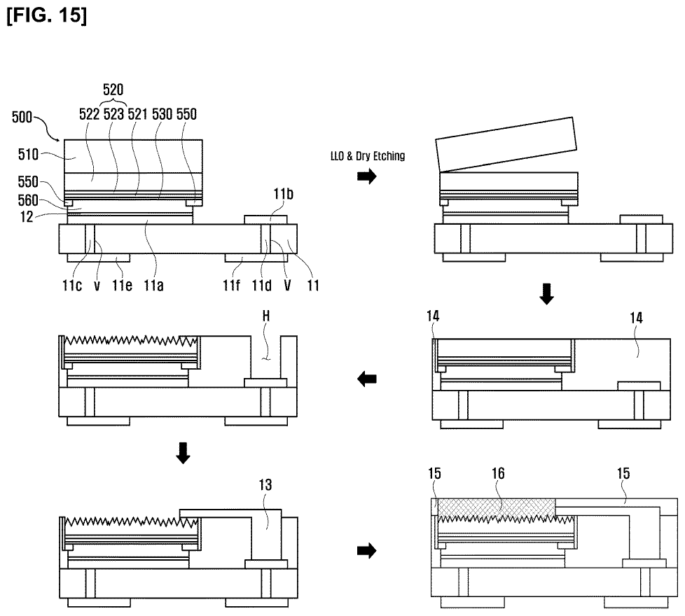

FIG. 14 is a flowchart of the method of manufacturing the semiconductor light-emitting device employing a color conversion technique according to the fifth embodiment of the present invention, and FIG. 15 illustrates a process of manufacturing the semiconductor light-emitting device employing a color conversion technique according to the fifth embodiment of the present invention.

As shown in FIGS. 14 and 15, the method (S50) of manufacturing the semiconductor light-emitting device employing a color conversion technique according to the fifth embodiment of the present invention includes a first operation S51, a second operation S52, a third operation S53, a fourth operation S54, a fifth operation S55, and a sixth operation S56. However, it is of course possible to change the order of the processes shown in FIGS. 14 and 15.

The first operation S51 is an operation of preparing an epitaxial die 500 according to the fifth embodiment of the present invention and a substrate part 11.

The epitaxial die 500 according to the fifth embodiment of the present invention includes a final support substrate 510, a light-emitting part 520 that generates light, a first ohmic electrode 530, a passivation layer 550, and a bonding pad layer 560 that is exposed to the outside.

The final support substrate 510 supports the light-emitting part 520, the first ohmic electrode 530, a contact electrode 540, the passivation layer 550, and the bonding pad layer 560, and a sapphire initial growth substrate may be used thereas. The light-emitting part 520 to be described below may be epitaxially grown on the final support substrate 510.

Meanwhile, in the present invention, the final support substrate 510 that supports the light-emitting part 520, the first ohmic electrode 530, the contact electrode 540, the passivation layer 550, and the bonding pad layer 560 is an initial growth substrate on which the light-emitting part 520 is grown.

The light-emitting part 520 generates light, and details of a first semiconductor region 521, a second semiconductor region 522, and an active region 523 are the same as those of the above-described method (S10) of manufacturing the semiconductor light-emitting device using the epitaxial die according to the first embodiment of the present invention, and thus redundant descriptions will be omitted.

The first ohmic electrode 530 is electrically connected to the first semiconductor region 521 of the light-emitting part 520 and is formed on the first semiconductor region 521 to cover and come into surface contact with an upper surface of the first semiconductor region 521. At this time, the first semiconductor region 521 is electrically connected to the first ohmic electrode 530 through a p-ohmic contact.

The first ohmic electrode 530 may be basically formed of materials that have high transparency or reflectance and excellent electrical conductivity, but the present invention is not limited thereto. The materials of the first ohmic electrode 530 may include optically transparent materials such as indium tin oxide (ITO), ZnO, indium zinc oxide (IZO), indium gallium zinc oxide (IGZO), and titanium nitride (TiN), and optically reflective materials such as Ag, Al, Rh, Pt, Ni, Pd, Ru, Cu, and Au, which may be used alone or in combination.

The passivation layer 550 covers a side portion of the first ohmic electrode 530, and may have a shape that covers one side and the other side of the first ohmic electrode 530.

The passivation layer 550 may be implemented with electrically insulating materials, and may include, for example, a single layer or multiple layers including at least one material from among silicon oxide, silicon nitride, metallic oxides including Al2O3, and organic insulators.

The bonding pad layer 560 functions as a vertical chip die bonding pad, and is formed on the first ohmic electrode 530 and the passivation layer 550 to be electrically connected to the first ohmic electrode 530. At this time, the bonding pad layer 560 is electrically connected to the first ohmic electrode 530, is exposed to the outside, and functions as a positive electrode.

The bonding pad layer 560 may include a diffusion barrier layer made of high melting point metals (such as Cr, V, Ti, W, Mo, and Re), or metals with high atomic packing density (such as Pt and Ni), and may basically include low melting point metals and noble metals such as gold (Au), silver (Ag), copper (Cu), and palladium (Pd), but the present invention is not limited thereto. In addition, the low melting point metals of the bonding pad layer 560 may be formed of metals such as In, Sn, Zn, and Pb alone or alloys including these metals.

Meanwhile, in the epitaxial die 500 according to the fifth embodiment of the present invention, the contact electrode 540 is not formed because the contact electrode 540 is formed and exposed on an upper surface of the second semiconductor region 522 after being transferred (placed) onto the substrate part 11. As a result, only the bonding pad layer 560, which functions as a positive electrode, is exposed to the outside.

Meanwhile, details of the substrate part 11 are the same as those of the method (S10) of manufacturing the semiconductor device employing a color conversion technique according to the first embodiment of the present invention described above, and thus redundant descriptions will be omitted.

The second operation S52 is an operation of placing the epitaxial die 500 upside down on a first upper electrode pad 11a, and electrically connecting the first upper electrode pad 11a and the bonding pad layer 560 by bonding them through a bonding layer 12.

The third operation S53 is an operation of separating the final support substrate 510 of the epitaxial die 500.

The fourth operation S54 is an operation of etching the epitaxial die 500 into a plurality of regions, and forming and exposing the contact electrode 540 on an upper surface of the light-emitting part 520. That is, the contact electrode 540 is electrically connected to the second semiconductor region 522 of the light-emitting part 520, and may be formed on one side of the upper surface of the second semiconductor region 522.

At this time, in the fourth operation S54, the epitaxial die 500 may be divided into a plurality of regions by etching the epitaxial die 500 to the extent that the light-emitting part 520 is fully isolated into separate parts (full isolation), or by etching the epitaxial die 500 only up to a portion of the light-emitting part 520 using the MESA process. Further, in the fourth operation S54, the epitaxial die 500 may be divided into three regions so that the epitaxial die 500 emits three types of light, such as blue, green, and red light, but the present invention is not limited thereto, and the epitaxial die 500 may be divided into a greater number of regions. For example, in the fourth operation S54, according to the design, the epitaxial die 500 may be divided into six regions, which form two pixels emitting each of blue, green, and red light. In this case, when one pixel is defective, the other pixel can replace the defective pixel, thereby providing the advantage of redundancy to maintain functionality despite defects.

Meanwhile, in the fourth operation S54, a surface texture pattern of a predetermined shape or an irregular shape may be formed on an upper surface of the light-emitting part 520, i.e., the upper surface of the second semiconductor region 522, of the upside-down epitaxial die 500 to extract as much light generated in the active region 523 into the air as possible.

The fifth operation S55 is an operation of forming an extension electrode 13 that electrically connects a second upper electrode pad 11b and the contact electrode 540. More specifically, in the fifth operation S55, laser drilling is used to etch a mold part 14 above the second upper electrode pad 11b to form a through hole H, and the extension electrode 13 is formed to extend vertically from an upper portion of the second upper electrode pad 11b to above the mold part 14 through the through hole H and then be bent toward the contact electrode 540, thereby electrically connecting the contact electrode 540 and the second upper electrode pad 11b.

Meanwhile, undescribed details of the second to sixth operations S52 to S56 are the same as those of the method (S10) of manufacturing the semiconductor device employing a color conversion technique according to the first embodiment of the present invention described above, and thus redundant descriptions will be omitted.

[symbol]

Although all the components constituting the embodiments of the present invention have been described as being combined or combined to operate as one, the present invention is not necessarily limited to the embodiments. That is, one or more of all the components may be combined to operate as one within the scope of the present invention.

Further, since terms such as “comprising,” “including,” or “having” may mean that the corresponding component can be included unless otherwise stated, it should be construed that another component is not excluded but may be further included. Unless defined otherwise, all terms used herein, including technical or scientific terms, have the same meanings as those generally understood by those skilled in the art to which the present invention pertains. Commonly used terms, such as terms defined in dictionaries, should be interpreted as being consistent with the contextual meaning of the related art and are not interpreted with ideal or excessively formal meanings unless explicitly defined herein.

In addition, the above description is merely an exemplary description of the technical spirit of the present invention, and the present invention may be subjected to various modifications and variations made by those skilled in the art to which the present invention pertains without departing from the essential features of the present invention.

Accordingly, the embodiments disclosed in the present invention are not provided to limit the technical spirit of the embodiments of the present invention but are provided to describe the present invention, and the scope of the technical spirit of the present invention is not limited by the embodiments. The scope of protection of the present invention should be construed from the attached claims, and all the technical ideas within the equivalent ranges fall within the scope of the present invention.

1. A method of manufacturing a semiconductor light-emitting device employing a color conversion technique that utilizes an epitaxial die, wherein the epitaxial die is formed by separating into die units, and is formed as a semi-finished product in which only one of the two electrodes is exposed to the outside, and functions as a pixel after being individually transferred to a substrate part, comprising:
a first operation of preparing an epitaxial die including a support substrate, a light-emitting part that generates light, an ohmic electrode electrically connected to the light-emitting part through an ohmic contact, a contact electrode that is not exposed to the outside, and a bonding pad layer that is exposed to the outside, and preparing a substrate part on which a first electrode pad and a second electrode pad are formed on its upper surface;
a second operation of placing the epitaxial die on the first electrode pad so that the bonding pad layer faces the first electrode pad, and bonding and electrically connecting the first electrode pad and the bonding pad layer through a bonding layer;
a third operation of separating the support substrate and expose the light-emitting part to the outside;
a fourth operation of dividing the light-emitting part into a plurality of regions by etching the exposed light-emitting part, forming a mold part on the substrate part to surround the epitaxial die, and then etching the mold part to expose the contact electrodes of each of the divided plurality of regions to the outside;
a fifth operation of etching the mold part to expose the second electrode pad to the outside and forming an extension electrode that electrically connects the exposed second electrode pad and the exposed contact electrode; and
a sixth operation of forming a color conversion layer over the divided plurality of regions of the light-emitting part, so that each of the divided plurality of regions of the light-emitting part emits light at different wavelengths,
wherein the mold part is formed so that its upper surface is lower than the upper surface of the extension electrode.

2. The method of claim 1, wherein the method of manufacturing a semiconductor light-emitting device further includes a sixth operation of forming a black matrix covering the extension electrode and mold part.

3. The method of claim 1, wherein the epitaxial die emits blue or ultraviolet (UV) light.

4. The method of claim 1, wherein the epitaxial die includes an etching stop layer, and the etching stop layer is formed between the light-emitting part and the ohmic electrode,
wherein, in the third operation, dividing the epitaxial die into plurality of regions by etching it down to the etching stop layer.

5. The method of claim 1, wherein the first electrode pad is common electrode, and the second electrode pad is individual electrode.

6. The method of claim 5, wherein the substrate part is formed with a first electrode post and a second electrode post through via holes, and the first electrode pad is electrically connected to the first electrode post, and the second electrode pad is electrically connected to the second electrode post.

7. The method of claim 6, wherein the via holes are formed at each corner of the substrate part.
